(19) United States
(12) Patent Application Publication
(10) Pub. No.: US 2026/0148786 A1
(43) Pub. Date: May 28, 2026

(54) FUSE ZEROIZATION FOR SECURITY APPLICATIONS

(71) Applicant: Intel Corporation, Santa Clara, CA (US)

(72) Inventors: Yao-Feng Chang, Gilbert, AZ (US); Zhanping Chen, Hillsboro, OR (US); Jason G. Sandri, Gilbert, AZ (US)

(21) Appl. No.: 18/958,839

(22) Filed: Nov. 25, 2024

(51) Int. Cl. G11C 17/18; G11C 17/16

(52) U.S. Cl. CPC G11C 17/18; G11C 17/16

(57) ABSTRACT

Embodiments herein relate to solutions for zeroization of one-time programmable (OTP) fuses which store important data such as security data which should be kept inaccessible to an attacker in the case of a security event. One or more control circuits can ensure that the fuses in an array are provided in a high resistance state in response to the security event. In one approach, the fuses in the array are read to identify fuses in a low resistance state and these fuses are selectively programmed to a high resistance state. In another approach, the fuses are subject to a program bias regardless of whether they are in a low or high resistance state.

### BACKGROUND

Computing devices often rely on electrically programmable fuses (e-fuses) to store data in integrated circuits (ICs). The fuses can be used as a one-time programmable (OTP) read-only memory (ROM), and are suitable for applications in which important data such as security data is stored which should not be changed.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 depicts a cross-sectional view of an example semiconductor device 100 which includes an example fuse 150 formed in a metal layer M3, according to various embodiments.

FIG. 2 depicts a circuit 200 which includes a set of fuses 210, according to various embodiments.

FIG. 3 depicts a flowchart of an example security process for a set of fuses, according to various embodiments.

FIG. 4 depicts a flowchart of an example zeroization process consistent with block 302 of FIG. 3, where the fuses are read to identify fuses in a low resistance state and the identified fuses are programmed to a high resistance state, according to various embodiments.

FIG. 5 depicts a flowchart of an example zeroization process consistent with block 302 of FIG. 3, where fuses in a column are sensed concurrently to determine whether they are all in a high resistance state, according to various embodiments.

FIG. 6 depicts a flowchart of an example zeroization process consistent with block 302 of FIG. 3, where fuses are read to determine whether they are in a low or high resistance state, and corresponding data is stored in a memory for later use in programming the fuses determined to be in the low resistance state, according to various embodiments.

FIG. 7 depicts a flowchart of an example zeroization process consistent with block 302 of FIG. 3, where the fuses are subject to a program bias regardless of whether they are in a low or high resistance state, according to various embodiments.

FIG. 8A depicts example states of a set of fuses after being programmed with data consistent with block 100 of FIG. 3, according to various embodiments.

FIG. 8B depicts example states of a set of fuses after being programmed to erase the data of FIG. 8A, consistent with the zeroization process of block 302 of FIG. 3, according to various embodiments.

FIG. 9 depicts an example scanning electron microscope (SEM) image of fuses in a metal layer, showing an unprogrammed bit_38=0 and a bit_37=1 with 1× programming, according to various embodiments.

FIG. 10 depicts an example SEM image of fuses in a metal layer, showing a bit_36=1 with 2× programming and an unprogrammed scb bit=0, according to various embodiments.

FIG. 11 depicts an example SEM image of fuses in a metal layer, showing a bit_35=1 with 3× programming and a bit_34=1 with 4× programming, according to various embodiments.

FIG. 12 depicts an example SEM image of fuses in a metal layer, showing a bit_33=1 with 5× programming and a bit_32=1 with 6× programming, according to various embodiments.

FIG. 13 illustrates an example of components that may be present in a computing system 1350 for implementing the techniques (e.g., operations, processes, methods, and methodologies) described herein.

### DETAILED DESCRIPTION

As mentioned at the outset, electrically programmable fuses are suitable for applications in which important data such as security data is stored which should not be changed.

An e-fuse is a one-time programmable (OTP) fuse that is programmed by applying a voltage which causes a relatively large current to flow in a fusible link of the fuse. The current blows or ruptures the fuse, resulting in a relatively high resistance along the fusible link. For example, the resistance may increase by one or more orders of magnitude. An OTP fuse can therefore store one bit, e.g., a 0 bit, in a low resistance state or another bit, e.g., a 1 bit, in a high resistance state. The programming is irreversible as the fuse cannot return to the low resistance state. A set of fuses can be arranged in rows and column in an array to allow reading and writing of individual fuses.

OTP fuses are a form of read-only memory (ROM), also referred to as programmable ROM. OTP fuses are a key technology for embedded memory, for instance. Product applications include reconfigurable ROM, root-of-trust implementations (memory redundancy), on-chip security keys, and unit-level-traceability. These OTP fuse memories provide high density, reliable, available, and affordable information storage.

However, the OTP memories present a security risk since a fuse in a high resistance state cannot be returned to the low resistance state, and since the controller architecture of the OTP memories are configured to only allow one-time programming of a fuse. This is sometimes due to a gating issue in the controllers. Challenges are therefore encountered in keeping the fuse data inaccessible to others. For example, the data may include cryptographic or other security information which should be kept inaccessible to an attacker such as a business competitor or a military opponent, if the attacker were to gain access to the fuse array. One example scenario is where an attacker gains access to a device which includes the fuses, either remotely through a network or by gaining physical access to the device.

One approach to keeping the fuse data inaccessible in response to a security threat is to supply an excessive current or voltage to the fuse array to cause voids and open circuits. Another approach involves a heating element which heats up the circuit to destroy it. Another approach involves incorporation of a corrosive chemical which can be released under specific conditions to damage the circuit. However, these approaches increase the size and complexity of the circuit.

The solutions provided herein address the above and other disadvantages. In one aspect, an apparatus includes an array of OTP fuses and associated access transistors arranged in rows and column, a row driver and a column driver, and one or more control circuits, where the one or more control circuits are configured to ensure that each of the fuses is in a high resistance state in response to detecting a security event. With each fuse in the same state, the originally programmed data cannot be recovered, so that the data is erased.

In one approach, the fuses are read to identify fuses in a low resistance state and these fuses are selectively programmed to a high resistance state. In another approach, the fuses are subject to a program bias regardless of whether they are in a low or high resistance state.

The solutions allow multiple-time programming (MTP) memory to provide fuse zeroization, e.g., erasing the data in a set of fuses. The solutions provide Power, Performance, Area, and Cost (PPAC) benefits while maintaining high-security storage. The solutions are compatible with security requirements of different entities including federal agencies such as the National Institute of Standards and Technology (NIST).

The solutions provide a number of advantages, including integration into existing IC processes with no increase in circuit design complexity, and area and cost savings as compared to other metal fuse technologies. The PPAC benefits improve circuit design performance and architecture flow with chiplets/Intellectual Property (IP) circuits for artificial intelligence (AI), Internet of Things (IoT) devices, and various central processing unit (CPU) high-security applications, for example. The solutions are flexible in that they can perform zeroization on an entire array of fuses or just a selected portion of an array.

These and other features will be further apparent in view of the following discussion.

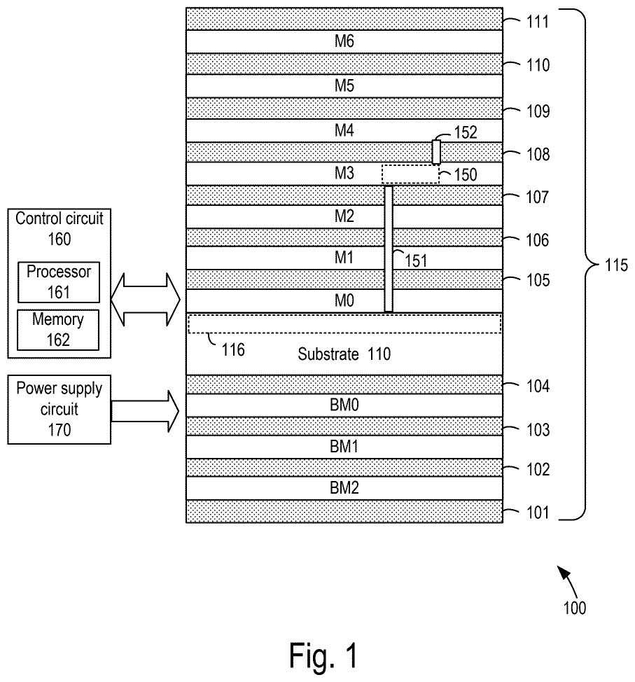

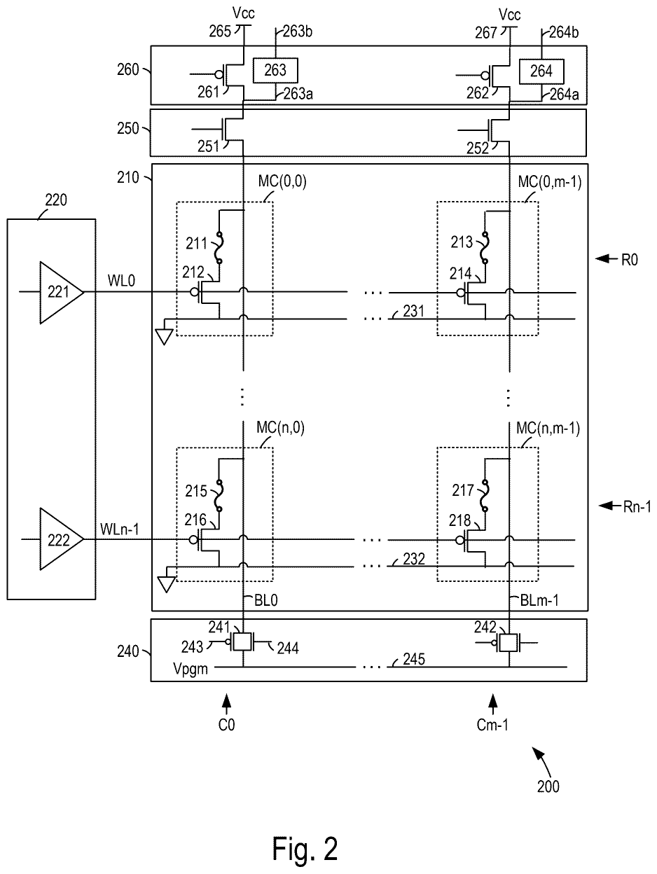

FIG. 1 depicts a cross-sectional view of an example semiconductor device 100 which includes an example fuse 150 formed in a metal layer M3, according to various embodiments. Generally, OTP fuses can comprise metal or polysilicon fuses. In this example, the fuse is formed in a top side metal layer of the device. The device 100 comprises a stack 115 of layers which include a substrate 110, a transistor region 116 in the substrate, top side metal layers M0-M6 which alternate with dielectric layers 105-111, and bottom side metal layers BM0-BM2 which alternate with dielectric layers 101-104. The transistor region 116 may include transistors of circuits, such as n-type or p-type metal-oxide-semiconductor field-effect transistor (MOSFETs). The circuits can include a word line driver, a bit line driver, a sense circuit, and column decoders for an array of fuses, for example, such as depicted in FIG. 2.

The example fuse 150 is coupled to the transistor region 116 by a via 151 and to M4 by a via 152, for example. The fuse comprises a relatively narrow portion of metal in the metal layer in this example. The narrow portion of metal is intentionally made weaker to act as a fusible element when excessive current flows through it. It is a weak spot in the metal pathway that will break or blow when overloaded. The use of M3 is an example only as other metal layers could be used. A polysilicon fuse, or polyfuse, can include a silicide layer covering a polysilicon line. Both types of fuses are programmed by applying a voltage across the fuse to permanently increase the resistance of the fuse.

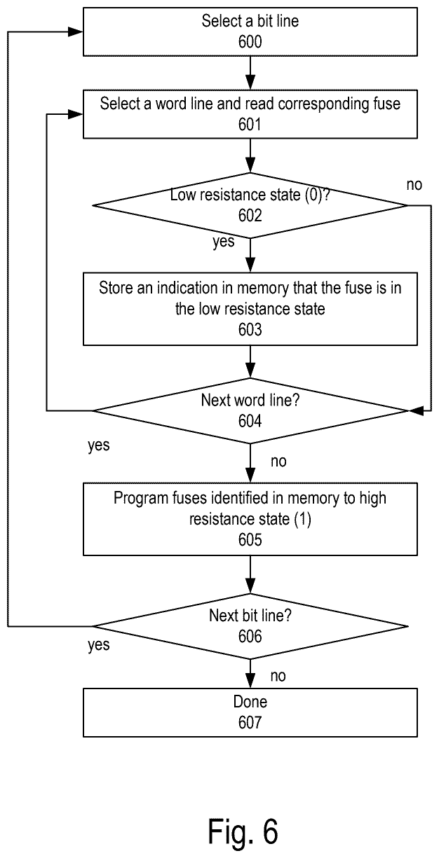

One or more control circuits 160 can provide control signals to an array of fuses and associated circuits such as the word line driver, bit line driver, sense circuit, and column decoder of FIG. 2. The one or more control circuits can include a memory 162 to store instructions and a processor 161 to execute the instructions to provide the features discussed herein. The memory can also store information regarding which fuses are in a low resistance state in connection with a zeroization process such as discussed in connection with FIG. 6, block 603.

Additionally, a power supply circuit 170 can include one or more voltage generators to provide power supply voltages such as Vcc to the one or more circuits.

FIG. 2 depicts a circuit 200 which includes a set of fuses 210, according to various embodiments. The fuses are arranged in a number n rows, R0 through Rn-1, and a number m columns, C0 through Cm-1, in an array. Each fuse is arranged in a memory cell, or unit cell, which includes an access transistor, in this example implementation. For example, the first row, R0, includes example memory cells MC(0,0) through MC(0,m-1) and the nth row includes example memory cells MC(n,0) through MC(n,m-1). MC(0,0) includes a fuse 211 and an access transistor 212, MC(0,m-1) includes a fuse 213 and an access transistor 214, MC(n,0) includes a fuse 215 and an access transistor 216, and MC(n,m-1) includes a fuse 217 and an access transistor 218. The access transistors are p-type MOSFETs in this example, so that an access transistor is turned on (made conductive) when a low voltage such as 0 V is applied to its control gate and turned off (made non-conductive) when a high voltage such as Vcc is applied to its control gate.

The control gates of the access transistors in each row are coupled to a common control line/word line (WL). For example, the control gates of the access transistors 212 and 214 are coupled to WL0, and the control gates of the access transistors 216 and 218 are coupled to WLn-1. Each word line in turn is driven by a respective word line driver, e.g., WL driver 221 for WL0 and WL driver 222 for WLn-1, in a word line decoder/driver circuit 220.

Each access transistor has a drain coupled to a ground path, and a source coupled to a respective fuse, in this example. For example, the access transistors in R0 have their drains coupled to a ground path 231, and the access transistors in Rn-1 have their drains coupled to a ground path 232. The access transistors 212, 214, 216 and 218 have their sources coupled to the fuses 211, 213, 215 and 217, respectively. The fuses have one side coupled to a respective access transistor and another side coupled to a respective bit line, in this example. In each memory cell, the fuse and the access transistor are in a series path. The access transistor is between the fuse and the ground path in this example, but other approaches are possible. For example, the access transistor could be between the fuse and the bit line, where the fuse is between the ground path and the access transistor.

The word lines and bit lines are first and second types of control lines, respectively, and could have their names reversed.

The fuses in each column are coupled to a common control line/bit line (BL). For example, the fuses 211 and 215 are coupled to BL0, and the fuses 213 and 217 are coupled to BLm-1. Each bit line is driven by a respective bit line driver, e.g., BL driver 241 for BL0 and BL driver 242 for BLm-1, in a bit decoder/driver circuit 240. The drivers are transmission gates in this example and include complementary control voltages at the control gates of the opposing n-type and p-type transistors. For example, the transmission gate 241 has control gates 243 and 244 of p-type and n-type transistors, respectively. Each transmission gate further includes an input coupled to a program voltage line 245 and an output coupled to a respective bit line. For example, the outputs of the transmission gates 241 and 242 are coupled to BL0 and BLm-1, respectively. The drivers could include a single transistor or a set of transistors other than in a transmission gate.

The bit lines extend along the columns of the array and are coupled to the fuses in each column. An opposing end of each bit line extends to a respective transistor at a bit line read decoder 250. For example, BL0 and BLm-1 are coupled to source/drains of transistors 251 and 252, respectively. The control gates of the transistors in the bit line read decoder 250 are coupled to control signals which allow selecting one transistor at a time. When a transistor in the bit line read decoder 250 is selected (turned on), the associated bit line is coupled to a sense circuit 260 so that a read/sense operation can be performed involving one or more memory cells coupled to the associated bit line in the associated column. The sense circuit can include sense amplifiers, in one approach, e.g., sense amplifiers 263 and 264 for BL0 and BLm-1, respectively. Each sense amplifier has a respective input coupled to a source/drain of a respective transistor which can be turned on to allow reading of the associated bit line. For example, sense amplifiers 263 and 264 have inputs 263a and 264a, respectively, coupled to transistors 261 and 262, respectively, which in turn are coupled to power supply nodes 265 and 267, respectively, at a power supply voltage Vcc. The control gates of the transistors in the sense circuit 260 are coupled to control signals which allow selecting one transistor at a time. The control signals can be provided by the one or more control circuits 160.

In a read operation for a selected memory cell in a selected column, the drivers in the bit decoder/driver circuit 240 are turned off. Respective transistors in the bit line read decoder 250 and the sense circuit 260 are turned on to couple the respective power supply node to the bit line. The word line of the selected memory cell is grounded to turn on the respective access transistor, while the word lines of the unselected memory cells are raised to turn off the respective access transistors. The voltage at an input to the respective sense amplifier of the selected column is sensed by the respective sense amplifier. When the fuse of the selected memory cell is in a low or high resistance state, the voltage at the input to the sense amplifier will be relatively low or high, respectively. The sense amplifier outputs a corresponding digital value to the one or more control circuits 160 indicating whether the fuse of the selected memory cell is in a low or high resistance state. For example, sense amplifiers 263 and 264 have outputs 263b and 264b, respectively.

For example, to read the memory cell MC(0,0), WL0 is grounded to turn on the respective access transistor 212. The remaining word line are raised in voltage to turn off the respective access transistors. The transmission gates 241 to 242 are turned off, and the transistors 251 and 261 are turned on.

It is also possible to concurrently sense whether a group of memory cells in a column are all in a high resistance state, as discussed further below.

In a program operation for a selected memory cell in a selected column, a corresponding driver in the bit decoder/driver circuit 240 is turned on. The corresponding transistors in the bit line read decoder 250 and the sense circuit 260 are turned off. A program voltage/pulse, Vpgm, is applied to the program voltage line 245 to generate a current to ground through the fuse and access transistor of the selected memory cell. An example magnitude for Vpgm is 1.8 V and an example pulse width is 20 μs, but these values can vary. The bias across the fuse is substantially equal to the magnitude of the program pulse. The program bias causes the fuse to transition from a low resistance state to a high resistance state.

For example, to program the memory cell MC(0,0), WL0 is grounded to turn on the associated access transistors including the access transistor 212. WL1 through WLn-1 are set high to turn off the associated access transistors to block a ground path and prevent programming of the associated fuses. The transistors in the bit line read decoder 250 and the sense circuit 260 are turned off. The transmission gate 241 is turned on to couple Vpgm from the control line 245 to BL0. A current then flows through BL0, the fuse 211, and the access transistor 212 to the ground path 231.

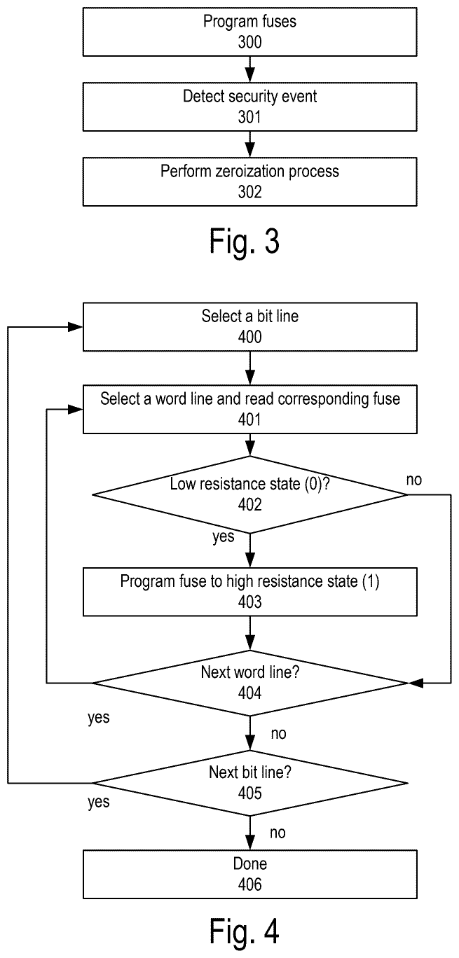

FIG. 3 depicts a flowchart of an example security process for a set of fuses, according to various embodiments. Block 300 includes programming the fuses, such as discussed in connection with FIG. 2. The programming can occur one fuse at a time, in one approach. Block 301 includes detecting a security event, e.g., an event which represents a security threat to the data stored in the fuses. For example, the security event can be triggered when a device containing the fuses is no longer in communication with another device. For example, the fuses may be in a vehicle such as drone or other aircraft which loses wireless communication with a base computing device for a threshold period of time. The vehicle may issue a security event to erase the data at this time. In another example, the security event occurs when a sensor on the vehicle indicates it has crashed. In another example, a device containing the fuses receives a security event as a wireless communication from another device. In another example, the security event occurs when a device containing the fuses determines that is has been tampered with. In another example, a device may issue a security event when a specified day/time is reached or when a timer reaches a threshold. Many other scenarios can trigger a security event.

Block 302 includes performing a zeroization process, e.g., a process to erase the data in a set of fuses. The zeroization process can involve ensuring that the fuses are in a high resistance state. In one approach, the zeroization is performed on an entire array of fuses. In another approach, the zeroization is performed on a selected portion of an array. For example, a portion of an array may include non-security data which need not be subject to zeroization in response to a security event, while another portion is subject to zeroization in response to the security event.

As mentioned, fuse zeroization refers to, e.g., erasing the data in a set of fuses. For example, the National Institute of Standards and Technology (NIST) defines in their Federal Information Processing Standards Publication (NIST-FIPS Publication 140) the term zeroization as a method of erasing electronically stored data, cryptographic keys, and Critical Security Parameters (CSPs) by altering or deleting the contents of the data storage to prevent recovery of the data. NIST further specifies zeroization as a cryptographic key management mechanism, where a cryptographic module should provide methods to zeroize all plaintext secret and private cryptographic keys and CSPs within the module.

FIG. 4 depicts a flowchart of an example zeroization process consistent with block 302 of FIG. 3, where the fuses are read to identify fuses in a low resistance state and the identified fuses are programmed to a high resistance state, according to various embodiments. Block 400 includes selecting a bit line/column. Block 401 includes selecting a word line/row and reading the corresponding fuse, e.g., the fuse in the selected column and row. A decision block 402 determines whether the fuse is in a low resistance state, e.g., data 0. If the answer is yes, block 403 includes programming the fuse to a high resistance state, e.g., data 1. Subsequently, a decision block 404 determines whether there is a next word line/fuse to select. The decision block 404 is also reached when the answer to the decision block 402 is no.

If there is a next word line to select, block 401 is reached again to select the next word line/row and read the corresponding fuse. If the answer to the decision block 404 is no, a decision block 405 determines whether there is a next bit line/column to select. If the answer to the decision block 405 is yes, block 400 is reached again to select a next bit line/column. If the answer to the decision block 405 is no, block 406 is reached where the process is done.

In one approach, the bit lines are selected one at a time in a sequence from the first bit line, e.g., BL0, to the last bit line, e.g., BLm-1. Also, for each selected bit line, the word lines can be selected one at a time in a sequence from the first word line, e.g., WL0, to the last word line, e.g., WLn-1.

In one approach, each fuse can be read and immediately programmed to the high resistance state if the fuse is determined to be in the low resistance state by the reading. The cells which are determined to already be in the high resistance state are not subject to a program bias in this example. This approach allows the low resistance fuses to be quickly identified and programmed without unnecessary biasing of already-programmed fuses. This approach saves time in the zeroization process since the read time is typically much less than the program time.

Also, when a low resistance fuse is identified and immediately programmed, before reading a next fuse, memory storage requirements in one or more control circuits are minimized. In another approach, discussed in connection with FIG. 6, multiple low resistance fuses in one or more columns can be identified by data stored in memory. This data is then accessed to determine which fuses to program.

The processes of FIGS. 4-7 select the fuses along a bit line/column before proceeding to a next bit line/column. This may be advantageous since, for a selected bit line, the transistors in the bit line read decoder 250 and the sense circuit 260 can be kept configured for reading as different fuses along the bit line are read. However, it is possible to select the fuses in a different order. For example, the fuses along a word line/row can be selected before proceeding to a next bit line/row.

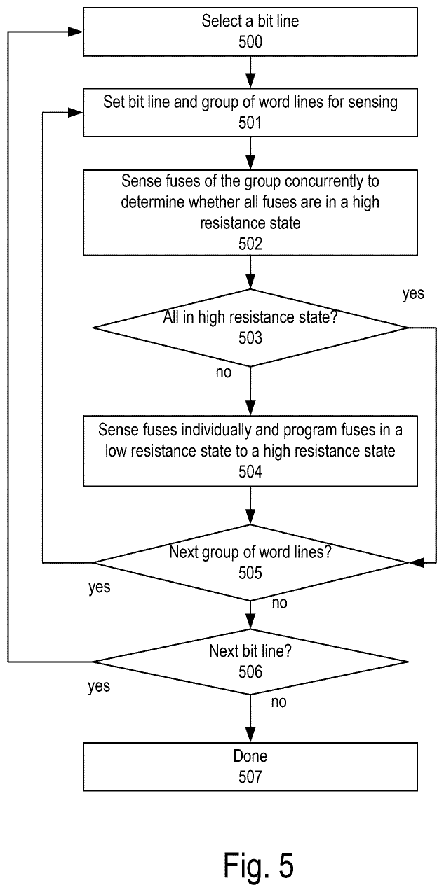

FIG. 5 depicts a flowchart of an example zeroization process consistent with block 302 of FIG. 3, where fuses in a column are sensed concurrently to determine whether they are all in a high resistance state, according to various embodiments. This approach can save time in the zeroization process by identifying multiple fuses in the high resistance state concurrently rather than in separate reads. Block 500 includes selecting a bit line. Block 501 includes setting the bit line and a group of word lines for sensing. For example, the group of word lines can be set to turn on the associated access transistors. The remaining word lines can be set to turn off the associated access transistors. The group can include two or more word lines, which are adjacent or non-adjacent.

Block 502 includes sensing the fuses of the group concurrently to determine whether all of the fuses in the group are in a high resistance state. If the sense amp outputs a 0, for example, this indicates the input to the sense node is at a low voltage and at least one of the fuses in the group is in a low resistance state. The voltage from the power supply node will go to a ground path of at least one fuses in the group which is in a low resistance state. If the sense amp outputs a 1, for example, this indicates the input to the sense node is at a high voltage and all of the fuses in the group are in a high resistance state.

A decision block 503 determines whether all of the fuses in the group are in a high resistance state. If the answer to the decision block 503 is yes, a decision block 505 is reached. The decision block 505 determines whether there is a next group of word lines to select for sensing. If the answer to the decision block 505 is yes, block 501 is reached again to set the bit line and a next group of word lines for sensing.

If the answer to the decision block 503 is no, block 504 involves sensing the fuses of the group individually and programming the fuses in a low resistance state to a high resistance state, after which the decision block 505 is reached.

If the answer to the decision block 505 is no, a decision block 506 determines whether there is a next bit line to select. If the answer to the decision block 506 is yes, block 500 is reached again to set a next bit line.

If the answer to the decision block 506 is no, block 507 indicates the process is done.

The group of fuses which is concurrently sensed can be all fuses in a column or just a subset of the fuses in a column. With a smaller group, there is a greater likelihood of detecting all fuses in a high resistance state and achieving a time savings compared to individual sensing of all fuses in a column. The technique can also quickly determine when one or more columns of an array have been programmed.

In one option, the number of fuses in a group is set adaptively. For example, if the sensing of one column in multiple groups indicates all cells are in a high resistance state, sensing of a next column can use a larger group size. It is also possible to progressively increase the group size in a single column when the cells of one group are in a high resistance state. The number of fuses can differ in different groups.

FIG. 6 depicts a flowchart of an example zeroization process consistent with block 302 of FIG. 3, where fuses are read to determine whether they are in a low or high resistance state, and corresponding data is stored in a memory for later use in programming the fuses determined to be in the low resistance state, according to various embodiments. Block 600 includes selecting a bit line/column. Block 601 includes selecting a word line/row and reading the corresponding fuse. A decision block 602 determines whether the fuse is in a low resistance state, e.g., data 0. If the answer is yes, block 603 includes storing an indication in memory, e.g., the memory 162 of the one or more control circuits 160, that the fuse is in the low resistance state.

Subsequently, a decision block 604 determines whether there is a next word line/fuse to select. The decision block 604 is also reached when the answer to the decision block 602 is no. If there is a next word line to select, block 601 is reached again to select the next word line/row and read the corresponding fuse. If the answer to the decision block 604 is no, block 605 is reached which includes programming the fuses identified in the memory (the low resistance fuses) to the high resistance state, e.g., data 1. For example, the low resistance fuses can be programmed one at a time by applying a program bias.

A decision block 606 determines whether there is a next bit line/column to select. If the answer to the decision block 606 is yes, block 600 is reached again to select a next bit line/column. If the answer to the decision block 606 is no, block 607 is reached where the process is done. This approach identifies the low resistance fuses for one bit line/column, then programs those identified fuses before reading the next bit line/column. Another approach includes reading the fuses of more than one column before programming the low resistance fuses. Another approach includes reading just a subset of the fuses of a column before programming the low resistance fuses.

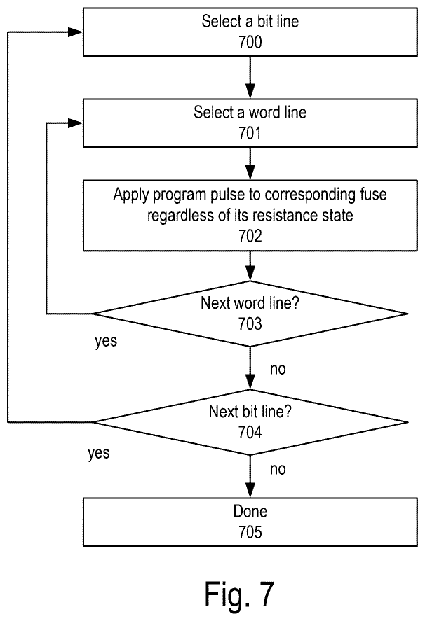

FIG. 7 depicts a flowchart of an example zeroization process consistent with block 302 of FIG. 3, where the fuses are subject to a program bias regardless of whether they are in a low or high resistance state, according to various embodiments. In this approach, the fuses can be subject to a program bias without reading them to determine their resistance state. Block 700 includes selecting a bit line/column. Block 701 includes selecting a word line/row. Block 702 includes applying a program pulse or bias to the corresponding fuse regardless of its resistance state, e.g., regardless of whether the respective fuse is in a low or high resistance state. The program bias will program a low resistance fuse to the high resistance state. A fuse which is already programmed to the high resistance state will remain in that state when subject to the program bias again.

Subsequently, a decision block 703 determines whether there is a next word line/fuse to select. If there is a next word line to select, block 701 is reached again to select the next word line/row. If the answer to the decision block 702 is no, a decision block 703 is reached which determines whether there is a next bit line/column to select. If the answer to the decision block 704 is yes, block 700 is reached again to select a next bit line/column. If the answer to the decision block 704 is no, 705 is reached where the process is done.

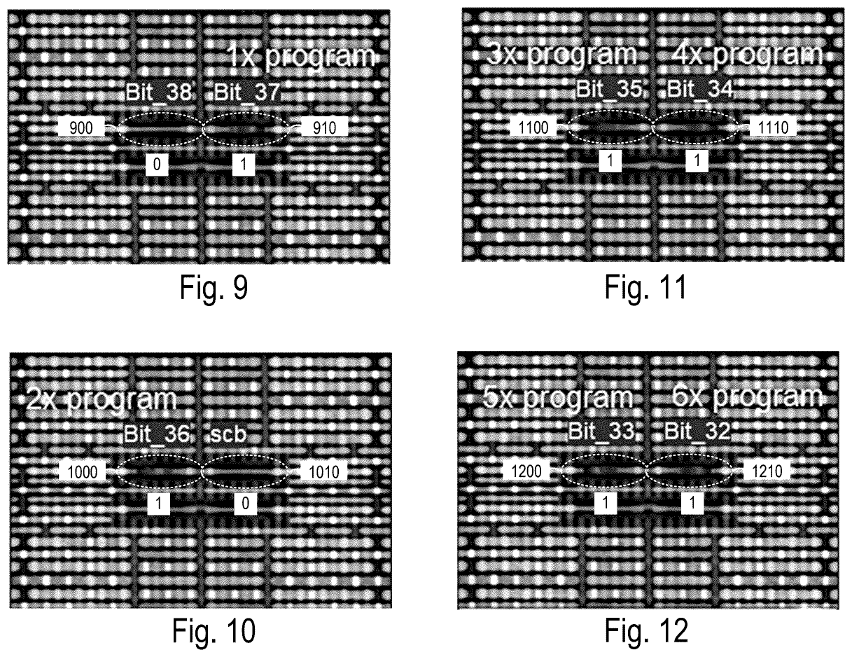

When a program bias is applied to a low resistance fuse, it transitions to the high resistance state. When a program bias is applied to a high resistance fuse, it remains in the high resistance state. As discussed further in connection with FIGS. 9-12, multiple program biases can be applied to fuses without damaging the fuses or associated circuits.

This approach can reduce the complexity of the control circuit as it avoids having to read fuses to identify low resistance fuses. However, the time to complete the zeroization is longer as each fuse is subject to a program bias.

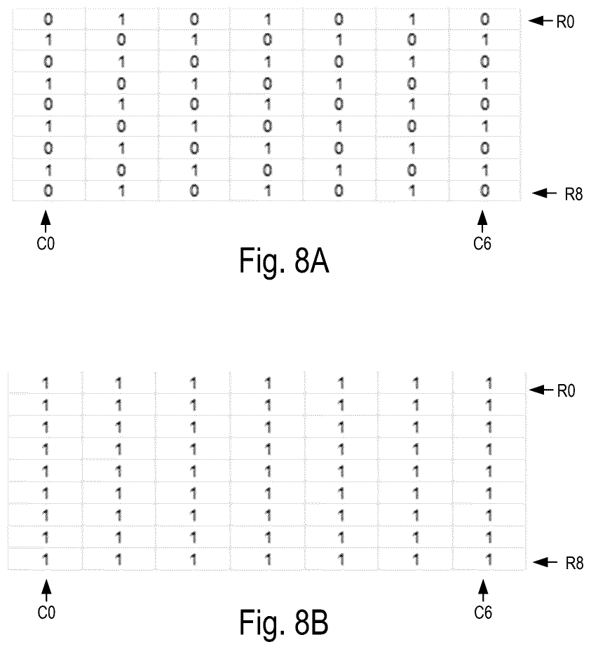

FIG. 8A depicts example states of a set of fuses after being programmed with data consistent with block 300 of FIG. 3, according to various embodiments. The set of fuses is arranged in an array of m=7 columns, C0-C6, and n=9 rows, R0-R8, consistent with FIG. 2. The data may represent security data which should be erased when a security event is detected. In this example, the first row, R0, includes bits 0, 1, 0, 1, 0, 1, 0 in columns C0-C6, respectively.

FIG. 8B depicts example states of a set of fuses after being programmed to erase the data of FIG. 8A, consistent with the zeroization process of block 302 of FIG. 3, according to various embodiments. The data is erased by setting all fuses to the high resistance state represented by data 1 in this example. Alternatively, the bit values could be switched so that the high resistance state is represented by data 0. In this example, in the first row, R0, the fuses in columns C0, C2, C4, and C6 are programmed to the high resistance state while the fuses in columns C1, C3 and C5 remain in the high resistance state.

FIG. 9 depicts an example scanning electron microscope (SEM) image of fuses in a metal layer, showing an unprogrammed bit_38=0 and a bit_37=1 with 1× programming, according to various embodiments. In FIGS. 9-12, the fuses are in metal layer M3, consistent with FIG. 1. The images provide a top down view of the semiconductor device. FIGS. 9-12 provide a passive voltage contrast (PVC) inspection of the fuses which have been subject to a program bias multiple times. The program bias is 1.8 V. PVC is a technique that uses an electron beam to examine the surface conductivity of semiconductors. In PVC, the electron beam of a SEM creates a voltage contrast between areas in the contacts where electrons are being charged or discharged.

The images show a light area where the fuse is intact and a dark area or voids where the fuse is blown and not present. The dark contrast level is essentially the same for the multiple-time programmed fuses/bits and for the one-time programmed fuses/bits.

Example fuses 900 and 910 represents a bit_38 and a bit_37, respectively, in an array. The fuse 900 is intact or continuous and therefore represents the low resistance state (0). The fuse 910 is blown or discontinuous and therefore represents the high resistance state (1). The fuse 910 has been programmed once.

FIG. 10 depicts an example SEM image of fuses in a metal layer, showing a bit_36=1 with 2× programming and an unprogrammed scb bit=0, according to various embodiments. Example fuses 1000 and 1010 represent a bit_36 and a bit scb, respectively, in an array. The fuse 1000 is blown and therefore represents the high resistance state (1), while the fuse 1010 is intact and therefore represents the low resistance state (0). The fuse 1000 has been programmed twice. Or, more precisely, the fuse 1000 has been programmed once with a first program bias and then subject to a second program bias. FIG. 11 depicts an example SEM image of fuses in a metal layer, showing a bit_35=1 with 3× programming and a bit_34=1 with 4× programming, according to various embodiments. Example fuses 1100 and 1110 represent a bit_35 and a bit_34, respectively, in an array. The fuses 1100 and 1110 are blown and therefore represent the high resistance state (1). The fuse 1100 has been programmed once with a first program bias and subject a second and third program biases. The fuse 1110 has been programmed once with a first program bias and then subject second-fourth program biases.

FIG. 12 depicts an example SEM image of fuses in a metal layer, showing a bit_33=1 with 5× programming and a bit_32=1 with 6× programming, according to various embodiments. Example fuses 1200 and 1210 represent a bit_33 and a bit_32, respectively, in an array. The fuses 1200 and 1210 are blown and therefore represent the high resistance state (1). The fuse 1200 has been programmed once with a first program bias and then subject to second-fifth program biases. The fuse 1210 has been programmed once with a first program bias and then subject to second-sixth program biases.

There is no clear trend that the multiple-time programmed fuses have larger voids. There is no damage to the fuse itself, or surrounding fuses and surrounding decode/control logic. The images thus demonstrate the viability of applying multiple program biases to the fuses in a zeroization process.

Other testing confirmed the viability as well. This testing mimicked a real-life product usage with multiple cycles of programming followed by endurance. The testing resulted in no yield or reliability failure.

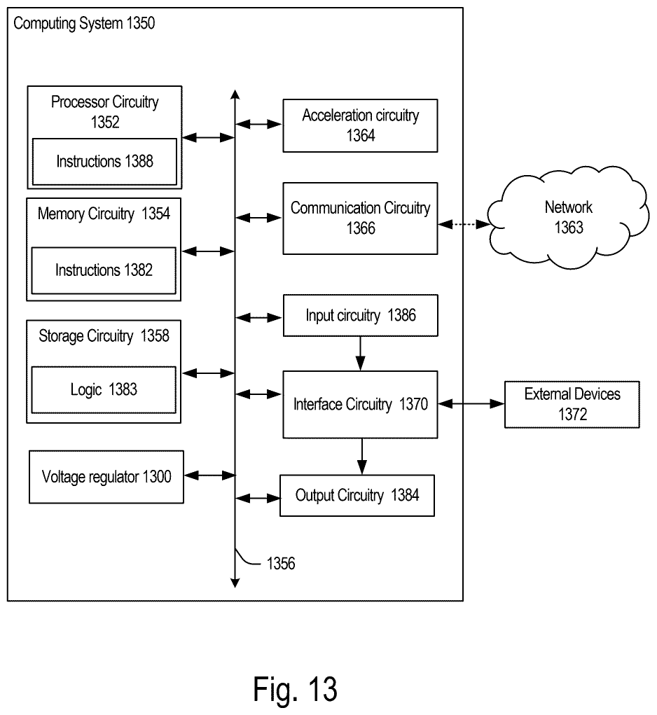

FIG. 13 illustrates an example of components that may be present in a computing system 1350 for implementing the techniques (e.g., operations, processes, methods, and methodologies) described herein.

The computing system 1350 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 1350, or as components otherwise incorporated within a chassis of a larger system. In an example implementation, the example circuit 200 which includes a fuse array 210 can be provided in the memory circuitry 1354 or the storage circuitry 1358, for example. The one or more associated circuits 160 can be provided in the processor circuitry 1352, the memory circuitry 1354, or the storage circuitry 1358, for example.

In one approach, all or part of the computing system 1350 is provided in a SoP, System in Package (SiP) or a System on Chip (SoC).

The voltage regulator 1300 can provide a voltage Vout to one or more of the components of the computing system 1350. The memory circuitry 1354 may store instructions and the processor circuitry 1352 may execute the instructions to perform the functions described herein.

The system 1350 includes processor circuitry in the form of one or more processors 1352. The processor circuitry 1352 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 1352 may include one or more hardware accelerators (e.g., same or similar to acceleration circuitry 1364), which may be microprocessors, programmable processing devices (e.g., FPGA, ASIC, etc.), or the like. The one or more accelerators may include, for example, computer vision and/or deep learning accelerators. In some implementations, the processor circuitry 1352 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein.

The processor circuitry 1352 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 1352 may be coupled with or may include memory/storage and may be configured to execute instructions stored in the memory/storage to enable various applications or operating systems to run on the platform 1350. The processors (or cores) 1352 is configured to operate application software to provide a specific service to a user of the platform 1350. In some embodiments, the processor(s) 1352 may be a special-purpose processor(s)/controller(s) configured (or configurable) to operate according to the various embodiments herein.

As examples, the processor(s) 1352 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 1352 may be a part of a system on a chip (SoC), System-in-Package (SiP), a multi-chip package (MCP), and/or the like, in which the processor(s) 1352 and other components are formed into a single integrated circuit, or a single package, such as the Edison™ or Galileo™ SoC boards from Intel® Corporation. Other examples of the processor(s) 1352 are mentioned elsewhere in the present disclosure.

The system 1350 may include or be coupled to acceleration circuitry 1364, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 1364 may comprise logic blocks or logic fabric and other interconnected resources that may be programmed (configured) to perform various functions, such as the procedures, methods, functions, etc. of the various embodiments discussed herein. In such implementations, the acceleration circuitry 1364 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 1352 and/or acceleration circuitry 1364 may include hardware elements specifically tailored for machine learning and/or artificial intelligence (AI) functionality. In these implementations, the processor circuitry 1352 and/or acceleration circuitry 1364 may be, or may include, an AI engine chip that can run many different kinds of AI instruction sets once loaded with the appropriate weightings and training code. Additionally or alternatively, the processor circuitry 1352 and/or acceleration circuitry 1364 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPs™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 1352 and/or acceleration circuitry 1364 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin provided by Huawei®, and/or the like. In some hardware-based implementations, individual subsystems of system 1350 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 1350 also includes system memory 1354. Any number of memory devices may be used to provide for a given amount of system memory. As examples, the memory 1354 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 1354 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 1354 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 1358 provides persistent storage of information such as data, applications, operating systems and so forth. In an example, the storage 1358 may be implemented via a solid-state disk drive (SSDD) and/or high-speed electrically erasable memory (commonly referred to as “flash memory”). Other devices that may be used for the storage 1358 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 1354 and/or storage circuitry 1358 may also incorporate three-dimensional (3D) cross-point (XPOINT) memories from Intel® and Micron®.

The memory circuitry 1354 and/or storage circuitry 1358 is/are configured to store computational logic 1383 in the form of software, firmware, microcode, or hardware-level instructions to implement the techniques described herein. The computational logic 1383 may be employed to store working copies and/or permanent copies of programming instructions, or data to create the programming instructions, for the operation of various components of system 1350 (e.g., drivers, libraries, application programming interfaces (APIs), etc.), an operating system of system 1350, one or more applications, and/or for carrying out the embodiments discussed herein. The computational logic 1383 may be stored or loaded into memory circuitry 1354 as instructions 1382, or data to create the instructions 1382, which are then accessed for execution by the processor circuitry 1352 to carry out the functions described herein. The processor circuitry 1352 and/or the acceleration circuitry 1364 accesses the memory circuitry 1354 and/or the storage circuitry 1358 over the interconnect (IX) 1356. The instructions 1382 direct the processor circuitry 1352 to perform a specific sequence or flow of actions, for example, as described with respect to flowchart(s) and block diagram(s) of operations and functionality depicted previously. The various elements may be implemented by assembler instructions supported by processor circuitry 1352 or high-level languages that may be compiled into instructions 1388, or data to create the instructions 1388, to be executed by the processor circuitry 1352. The permanent copy of the programming instructions may be placed into persistent storage devices of storage circuitry 1358 in the factory or in the field through, for example, a distribution medium (not shown), through a communication interface (e.g., from a distribution server (not shown)), over-the-air (OTA), or any combination thereof.

The IX 1356 couples the processor 1352 to communication circuitry 1366 for communications with other devices, such as a remote server (not shown) and the like. The communication circuitry 1366 is a hardware element, or collection of hardware elements, used to communicate over one or more networks 1363 and/or with other devices. In one example, communication circuitry 1366 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 1366 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 1356 also couples the processor 1352 to interface circuitry 1370 that is used to connect system 1350 with one or more external devices 1372. The external devices 1372 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 1350, which are referred to as input circuitry 1386 and output circuitry 1384. The input circuitry 1386 and output circuitry 1384 include one or more user interfaces designed to enable user interaction with the platform 1350 and/or peripheral component interfaces designed to enable peripheral component interaction with the platform 1350. Input circuitry 1386 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 1384 may be included to show information or otherwise convey information, such as sensor readings, actuator position(s), or other like information. Data and/or graphics may be displayed on one or more user interface components of the output circuitry 1384. Output circuitry 1384 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 1350. The output circuitry 1384 may also include speakers and/or other audio emitting devices, printer(s), and/or the like. Additionally or alternatively, sensor(s) may be used as the input circuitry 1384 (e.g., an image capture device, motion capture device, or the like) and one or more actuators may be used as the output device circuitry 1384 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 1350 may communicate over the IX 1356. The IX 1356 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 1356 may be a proprietary bus, for example, used in a SoC based system.

The number, capability, and/or capacity of the elements of system 1350 may vary, depending on whether computing system 1350 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 1350 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Some non-limiting examples of various embodiments are presented below.

Example 1 includes an apparatus, comprising: a set of one-time programmable (OTP) fuses; respective access transistors coupled to respective OTP fuses of the set of OTP fuses; and one or more control circuits coupled to the respective access transistors and to the set of OTP fuses, wherein the one or more control circuits are configured to program data into the set of OTP fuses, and to erase the data from the set of OTP fuses.

Example 2 includes the apparatus of Example 1, wherein: in response to the programmed data, at least one of the OTP fuses of the set of OTP fuses is configured in a high resistance state and at least one of the OTP fuses of the set of OTP fuses is configured in a low resistance state; and to erase the data, the one or more control circuits are configured to identify the OTP fuses in the low resistance state, and apply a program bias across the OTP fuses in the low resistance state.

Example 3 includes the apparatus of Example 2, wherein: the one or more control circuits comprise a memory to store an indication of the OTP fuses in the low resistance state.

Example 4 includes the apparatus of Example 2 or 3, wherein: the one or more control circuits are configured to apply the program bias to one of the OTP fuses identified as being in the low resistance state before identifying another OTP fuse of the set of OTP fuses in the low resistance state.

Example 5 includes the apparatus of Example 2 or 3, wherein: the one or more control circuits are configured to identify multiple OTP fuses in the low resistance state before applying the program bias to the multiple OTP fuses in the low resistance state.

Example 6 includes the apparatus of any one of Examples 2-5, wherein: the one or more control circuits are configured to apply the program bias for the OTP fuses in the low resistance state one OTP fuse at a time.

Example 7 includes the apparatus of any one of Examples 2-6, wherein: the set of OTP fuses are coupled to a set of bit lines; and

the one or more control circuits are configured to concurrently sense whether a group of OTP fuses coupled to one of the bit lines is in a high resistance state.

Example 8 includes the apparatus of any one of Examples 1-7, wherein: the one or more control circuits are configured to trigger the erasing of the data from the set of OTP fuses in response to a security threat.

Example 9 includes the apparatus of any one of Examples 1-8, wherein: to erase the data, the one or more control circuits are configured to apply a program bias to respective OTP fuses of the set of OTP fuses regardless of whether the respective OTP fuses are in a low or high resistance state, to provide the respective OTP fuses of the set of OTP fuses in a high resistance state.

Example 10 includes the apparatus of Example 9, wherein: the one or more control circuits are configured to apply the program bias to multiple OTP fuses of the set of OTP fuses concurrently.

Example 11 includes the apparatus of any one of Examples 1-10, wherein: the set of OTP fuses, the respective access transistors and the one or more control circuits are provided in at least one of an integrated circuit, a System on Chip, a System in Package or a computing device.

Example 12 includes an apparatus, comprising: a memory configured to store instructions; and a processor coupled to the memory and configured to execute the instructions to: receive an indication of a security threat to data stored in a set of one-time programmable (OTP) fuses; and in response to the indication of the security threat, provide the set of OTP fuses in a high resistance state to erase the data.

Example 13 includes the apparatus of Example 12, wherein: to provide the set of OTP fuses in the high resistance state, the processor is configured to execute the instructions to identify respective OTP fuses of the set of OTP fuses in a low resistance state, and program the respective OTP fuses to the high resistance state.

Example 14 includes the apparatus of Example 13, wherein: the memory is configured to store data to identify the respective OTP fuses in the low resistance state.

Example 15 includes the apparatus of any one of Examples 12-14, wherein: to provide the set of OTP fuses in the high resistance state, the processor is configured to execute the instructions to apply a program bias to respective OTP fuses of the set of OTP fuses regardless of whether the respective OTP fuses are in a low or high resistance state.

Example 16 includes a system, comprising: a set of one-time programmable (OTP) fuses in columns and rows; a row driver coupled to the rows of OTP fuses; a column driver coupled to the column of OTP fuses; and one or more control circuits coupled to the row driver and the column driver, wherein the one or more control circuits are configured to control the row and column drivers to program data into the set of OTP fuses, wherein the programming is to transition some of the OTP fuses from a low resistance state to a high resistance state, wherein others of the OTP fuses remain in the low resistance state, and to erase the data, wherein the set of OTP fuses, when the data is erased, are in the high resistance state.

Example 17 includes the system of Example 16, wherein: to erase the data, the one or more control circuits are configured to read the set of OTP fuses to identify the OTP fuses in the low resistance state, and to apply a program bias across the OTP fuses in the low resistance state based on the reading.

Example 18 includes the system of Example 17, wherein: the reading includes concurrently sensing whether multiple OTP fuses in one of the columns are in a high resistance state.

Example 19 includes the system of any one of Examples 16-18, wherein: to erase the data, the one or more control circuits are configured to apply a program bias to respective OTP fuses of the set of OTP fuses.

Example 20 includes the system of any one of Examples 16-19, wherein: the OTP fuses comprise metal or polysilicon fuses.

Example 21 includes a method, comprising: programming data into a set of one-time programmable (OTP) fuses, then erasing the data, wherein the erasing of the data ensures that the set of OTP fuses are in a high resistance state.

Example 22 includes the method of Example 21, further comprising reading the set of OTP fuses to identify the OTP fuses in a low resistance state, wherein the erasing comprises applying a program bias across the OTP fuses identified to be in the low resistance state based on the reading.

Example 23 includes the method of Example 21 or 22, wherein the erasing comprises applying a program bias to respective OTP fuses of the set of OTP fuses regardless of whether the respective OTP fuses are in a low or high resistance state, to ensure the respective OTP fuses of the set of OTP fuses are in the high resistance state.

Example 24 includes the method of any one of Examples 21-23, further comprising triggering the erasing of the data from the set of OTP fuses in response to a security threat.

Example 25 includes the method of any one of Examples 21-24, wherein the set of OTP fuses are coupled to a set of bit lines, and the method further comprises concurrently sensing whether a group of OTP fuses coupled to one of the bit lines is in the high resistance state.

Example 26 includes an apparatus, comprising means to perform the method of any one of Examples 21-25.

Example 27 includes a machine-readable storage including machine-readable instructions which, when executed, cause a computer to implement the method of any one of Examples 21-25.

Example 28 includes a computer program comprising instructions which, when executed by a computer, cause the computer to carry out the method of any one of Examples 21-25.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus, comprising:
a set of one-time programmable (OTP) fuses;
respective access transistors coupled to respective OTP fuses of the set of OTP fuses; and
one or more control circuits coupled to the respective access transistors and to the set of OTP fuses, wherein the one or more control circuits are configured to program data into the set of OTP fuses, and erase the data from the set of OTP fuses.

2. The apparatus of claim 1, wherein:
in response to the programmed data, at least one of the OTP fuses of the set of OTP fuses is configured in a high resistance state and at least one of the OTP fuses of the set of OTP fuses is configured in a low resistance state; and
to erase the data, the one or more control circuits are configured to identify the OTP fuses in the low resistance state, and apply a program bias across the OTP fuses in the low resistance state.

3. The apparatus of claim 2, wherein the one or more control circuits comprise a memory to store an indication of the OTP fuses in the low resistance state.

4. The apparatus of claim 2, wherein the one or more control circuits are configured to apply the program bias to one of the OTP fuses identified as being in the low resistance state before identifying another OTP fuse of the set of OTP fuses in the low resistance state.

5. The apparatus of claim 2, wherein the one or more control circuits are configured to identify multiple OTP fuses in the low resistance state before applying the program bias to the multiple OTP fuses in the low resistance state.

6. The apparatus of claim 2, wherein the one or more control circuits are configured to apply the program bias for the OTP fuses in the low resistance state one OTP fuse at a time.

7. The apparatus of claim 2, wherein:
the set of OTP fuses are coupled to a set of bit lines; and
the one or more control circuits are configured to concurrently sense whether a group of OTP fuses coupled to one of the bit lines is in a high resistance state.

8. The apparatus of claim 1, wherein the one or more control circuits are configured to trigger the erasing of the data from the set of OTP fuses in response to a security threat.

9. The apparatus of claim 1, wherein to erase the data, the one or more control circuits are configured to apply a program bias to respective OTP fuses of the set of OTP fuses regardless of whether the respective OTP fuses are in a low or high resistance state, to provide the respective OTP fuses of the set of OTP fuses in a high resistance state.

10. The apparatus of claim 9, wherein the one or more control circuits are configured to apply the program bias to multiple OTP fuses of the set of OTP fuses concurrently.

11. The apparatus of claim 1, wherein the set of OTP fuses, the respective access transistors and the one or more control circuits are provided in at least one of an integrated circuit, a System on Chip, a System in Package or a computing device.

12. An apparatus, comprising:
a memory configured to store instructions; and
a processor coupled to the memory and configured to execute the instructions to:
receive an indication of a security threat to data stored in a set of one-time programmable (OTP) fuses; and
in response to the indication of the security threat, provide the set of OTP fuses in a high resistance state to erase the data.

13. The apparatus of claim 12, wherein to provide the set of OTP fuses in the high resistance state, the processor is configured to execute the instructions to identify respective OTP fuses of the set of OTP fuses in a low resistance state, and program the respective OTP fuses to the high resistance state.

14. The apparatus of claim 13, wherein the memory is configured to store data to identify the respective OTP fuses in the low resistance state.

15. The apparatus of claim 12, wherein to provide the set of OTP fuses in the high resistance state, the processor is configured to execute the instructions to apply a program bias to respective OTP fuses of the set of OTP fuses regardless of whether the respective OTP fuses are in a low or high resistance state.

16. A system, comprising:
a set of one-time programmable (OTP) fuses in columns and rows;
a row driver coupled to the rows of OTP fuses;
a column driver coupled to the column of OTP fuses; and
one or more control circuits coupled to the row driver and the column driver, wherein the one or more control circuits are configured to control the row and column drivers to program data into the set of OTP fuses, wherein the programming is to transition some of the OTP fuses from a low resistance state to a high resistance state, wherein others of the OTP fuses remain in the low resistance state, and to erase the data, wherein the set of OTP fuses, when the data is erased, are in the high resistance state.

17. The system of claim 16, wherein to erase the data, the one or more control circuits are configured to read the set of OTP fuses to identify the OTP fuses in the low resistance state, and to apply a program bias across the OTP fuses in the low resistance state based on the reading.

18. The system of claim 17, wherein the reading includes concurrently sensing whether multiple OTP fuses in one of the columns are in a high resistance state.

19. The system of claim 16, wherein to erase the data, the one or more control circuits are configured to apply a program bias to respective OTP fuses of the set of OTP fuses.

20. The system of claim 16, wherein the OTP fuses comprise metal or polysilicon fuses.
